(19) United States
(12) Patent Application Publication
(10) Pub. No.: US 2026/0293183 A1
(43) Pub. Date: Sep. 24, 2026

(54) EMBEDDED CHANNEL III-NITRIDE TRANSISTOR

(71) Applicant: Bin Lu, FREMONT, CA (US)

(72) Inventor: Bin Lu, FREMONT, CA (US)

(21) Appl. No.: 19/570,563

(22) Filed: Mar. 18, 2026

Related U.S. Application Data
(60) Provisional application No. 63/773,813, filed on Mar. 18, 2025.

(51) Int. Cl. H10D 30/47; H10D 30/01; H10D 62/824

(52) U.S. Cl. CPC H10D 30/475; H10D 30/015; H10D 62/824

(57) ABSTRACT

A III-nitride transistor device includes an embedded channel structure in which n-type doped III-nitride regions are formed over a back barrier layer and define a channel region therebetween. A channel layer and a gate structure are formed in the channel region, the gate structure comprising one or more of a barrier layer, a p-type III-nitride layer, and a gate dielectric layer. Source and drain electrodes are formed on the n-type doped III-nitride regions. The embedded channel structure replaces conventional 2DEG-based access regions with n-type doped III-nitride regions, which effectively shield against electron trapping. The elimination of 2DEG-based access regions improves saturation current and transconductance linearity. The device may operate in enhancement or depletion mode.

### CROSS-REFERENCE TO RELATED APPLICATIONS

This application claims the benefit of priority to U.S. Provisional Patent Application No. 63/773,813, filed on Mar. 18, 2025, entitled “Embedded Channel Structure,” the entire contents of which are incorporated herein by reference.

### BACKGROUND OF THE INVENTION

### Field of the Invention

The present invention relates to semiconductor devices, and more particularly to III-nitride based transistors incorporating an embedded channel structure with self-aligned source and drain regions that eliminate conventional access regions.

### Description of Related Art

Gallium nitride (GaN)-based high-electron-mobility transistors (HEMTs) are widely employed in power electronics and radio-frequency applications due to their wide bandgap, high critical electric field, high electron mobility, and high saturation velocity. Conventional GaN HEMTs include both depletion-mode (normally-on) devices, in which a gate electrode is formed directly on or over a barrier layer (e.g. AlGaN) with a negative threshold voltage, and enhancement-mode (normally-off) devices, in which additional gate structures such as a p-type GaN (pGaN) layer or a gate recess beneath the gate electrode are used to achieve a positive threshold voltage. Despite the commercial success of GaN-based HEMTs, conventional device architectures share several fundamental limitations.

First, in conventional GaN HEMTs, the channel layer and barrier layer extend continuously and uniformly between the source and drain contacts, forming two-dimensional electron gas (2DEG)-based access regions between the gate and the source and drain contacts. The trapping of electrons in these access regions depletes the 2DEG, causing current collapse and dynamic on-resistance degradation. In enhancement-mode devices employing a pGaN gate, the access region surfaces are additionally subjected to dry etching during pGaN removal from the access regions, which further exacerbates electron trapping in the access regions.

Second, the 2DEG sheet resistance and limited electron density in the access regions adds parasitic access resistance, limits the maximum saturation drain current (Idmax), reduces peak transconductance (gm), and increases gm nonlinearity of the transistor.

Third, precise ohmic recess etching into the AlGaN barrier is needed to form ohmic contacts to the 2DEG in the access regions that connect the source and drain electrodes to the channel underneath the gate electrode in conventional GaN HEMTs. To reduce contact resistance, additional regrowth of heavily doped n-type GaN (n+ GaN) in the ohmic recess is used, adding additional process complexity.

Efforts to reduce the 2DEG-based access region length were demonstrated by Shinohara et al., where dielectric sidewall spacers were used to separate the gate structure from the regrown n+ GaN in the source and drain ohmic contact regions. The thickness of the sidewall spacer determines the length of the 2DEG-based access region. While these devices demonstrated the benefits of reduced 2DEG-based access region limitations, the fabrication process introduces additional complexity, particularly related to the formation of the dielectric sidewall spacer prior to the gate contact and its compatibility with pGaN gate technology for enhancement-mode transistors.

Accordingly, there remains a need for an improved III-nitride transistor structure that can eliminate the 2DEG-based access region limitations, and simplify the process complexity associated with ohmic contacts and formation of self-aligned gate structures.

### BRIEF SUMMARY OF THE INVENTION

The present invention provides a III-nitride transistor device comprising an embedded channel structure in which n-type doped III-nitride regions are formed over a back barrier layer, and a channel layer is formed in a channel region between the n-type doped III-nitride regions, such that the n-type doped III-nitride regions are self-aligned to the channel and eliminate the 2DEG-based access regions in between. The embedded channel structure replaces the conventional 2DEG-based access regions with n-type doped III-nitride regions, in which the high doping density effectively shields against surface defect-induced electron trapping that afflicts conventional devices. The elimination of 2DEG-based access regions also increases saturation current and improves transconductance linearity. The n-type doped III-nitride regions further enable direct formation of low-resistance ohmic contacts without the complex process optimization required in conventional devices.

In one aspect, a transistor device is provided comprising: a substrate; a buffer layer over the substrate; a back barrier layer over the buffer layer; n-type doped III-nitride regions formed over the back barrier layer, the n-type doped III-nitride regions defining a channel region therebetween; a channel layer comprising a III-nitride semiconductor formed in the channel region over the back barrier layer; a gate structure formed over the channel layer in the channel region; a gate electrode formed over the gate structure; and source and drain electrodes formed on the n-type doped III-nitride regions on opposing lateral sides of the gate electrode. At least one of the gate structure and the gate electrode extends laterally to overlap with or be substantially aligned with an inner lateral edge of at least one of the n-type doped III-nitride regions.

The gate structure may take various forms. In a first embodiment, the gate structure comprises a barrier layer formed over the channel layer, the barrier layer comprising a III-nitride semiconductor having a wider bandgap than the channel layer, and the gate electrode is formed directly on the barrier layer. In a second embodiment, the gate structure comprises a barrier layer formed over the channel layer and a p-type III-nitride layer formed over the barrier layer, and the gate electrode is formed over the p-type III-nitride layer. In a third embodiment, the gate structure comprises a gate dielectric layer formed over the channel layer without an intervening barrier layer, and the gate electrode is formed on the gate dielectric layer. In a fourth embodiment, the gate structure comprises a barrier layer formed over the channel layer and a gate dielectric layer formed over the barrier layer, and the gate electrode is formed on the gate dielectric layer. Additional combinations of these layers are not precluded.

The channel layer and the gate structure layers may extend laterally beyond the channel region onto at least a portion of the top surface of the n-type doped III-nitride regions, or may be laterally confined within the channel region. In embodiments where these layers extend beyond the channel region, the n-type doped III-nitride regions are positioned underneath these layers in the overlap region.

The transistor device may be configured for enhancement-mode (normally-off) operation with a positive threshold voltage, or for depletion-mode (normally-on) operation with a negative threshold voltage, depending on the gate structure configuration, layer compositions, and layer thicknesses.

The invention also provides a method of fabricating such a transistor device, comprising forming the n-type doped III-nitride regions over the back barrier layer, forming the channel region, and forming the channel layer and gate structure in the channel region.

### BRIEF DESCRIPTION OF THE DRAWINGS

FIG. 1 is a cross-sectional view of a conventional GaN transistor with a pGaN gate over a uniform AlGaN barrier, illustrating the continuous channel and barrier layers extending between the source and drain contacts with 2DEG-based access regions (Prior Art).

FIG. 2 is a cross-sectional view of a transistor device according to a first embodiment of the invention, showing an embedded channel structure in which the channel layer and the barrier layer extend laterally beyond the channel region onto a portion of the top surface of the n-type doped III-nitride regions, with a p-type III-nitride layer formed over the barrier layer, and a gate electrode formed over the p-type III-nitride layer.

FIG. 3 is a cross-sectional view of a transistor device according to a second embodiment, wherein the channel layer is laterally confined within the channel region and the barrier layer extends laterally beyond the channel region onto a portion of the top surface of the n-type doped III-nitride regions, with a p-type III-nitride layer formed over the barrier layer.

FIG. 4 is a cross-sectional view of a transistor device according to a third embodiment, wherein the channel layer and the barrier layer extend laterally beyond the channel region onto a portion of the top surface of the n-type doped III-nitride regions, without a p-type III-nitride layer, and the gate electrode is formed directly on the barrier layer.

FIG. 5 is a cross-sectional view of a transistor device according to a fourth embodiment, wherein the channel layer, the barrier layer, and the p-type III-nitride layer are all laterally confined within the channel region and do not extend over the top surface of the n-type doped III-nitride regions, and a dielectric layer is formed on the n-type doped III-nitride regions on opposing lateral sides of the gate structure.

### DETAILED DESCRIPTION OF THE INVENTION

Reference will now be made in detail to embodiments of the invention, examples of which are illustrated in the accompanying drawings. The same reference numbers are used throughout to refer to the same or like elements.

### I. Prior Art

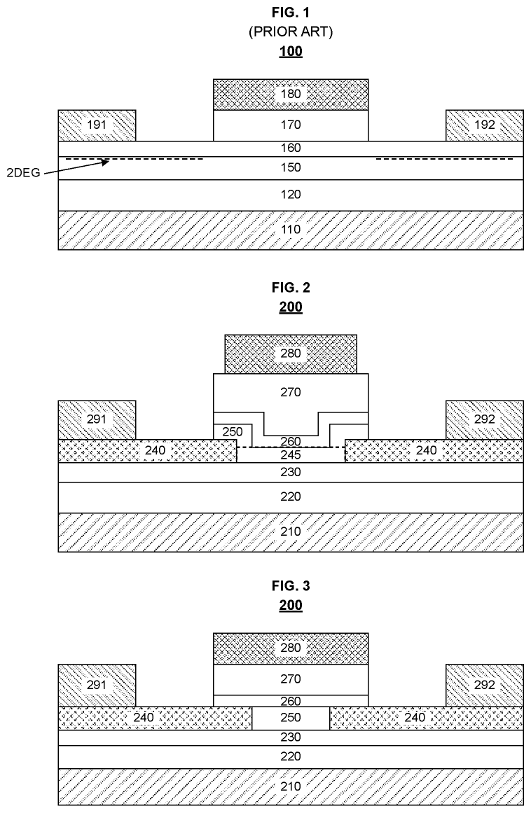

Referring to FIG. 1, a conventional GaN transistor 100 includes a substrate 110, a buffer layer 120, a channel layer 150 formed over the buffer layer 120, a barrier layer 160 formed over the channel layer 150, a p-type III-nitride (pGaN) layer 170 formed over a portion of the barrier layer 160, a gate electrode 180 formed over the p-type III-nitride layer 170, and a source electrode 191 and drain electrode 192 formed on the barrier layer 160 on opposing lateral sides of the gate electrode 180. The channel layer 150 and the barrier layer 160 extend continuously and uniformly between the source electrode 191 and the drain electrode 192, forming 2DEG-based access regions between the gate electrode 180 and the source and drain electrodes 191, 192. These access regions are subject to surface defects, electron trapping, parasitic resistance, and ohmic contact challenges that limit device performance.

### II. Overview

The present invention provides a III-nitride transistor device with an embedded channel structure that is applicable to a range of device configurations, including depletion-mode transistors, enhancement-mode transistors, transistors with a p-type III-nitride layer under the gate electrode, transistors with a gate dielectric, and other gate structure variants. The common structural feature across all embodiments is the embedded channel formed in a channel region between n-type doped III-nitride regions, with the n-type doped III-nitride regions self-aligned to the channel.

### III. Common Layers

The following layers are common to all embodiments described herein. The substrate 210 may comprise silicon (Si), silicon carbide (SiC), sapphire, or other suitable materials. The buffer layer 220 accommodates lattice and thermal mismatch between the substrate 210 and the III-nitride epitaxial layers, and provides electrical isolation. The buffer layer 220 may comprise one or more layers of AlN, AlGaN, or GaN, optionally with compensation doping (e.g., carbon or iron).

The back barrier layer 230 is formed over the buffer layer 220 and comprises a III-nitride semiconductor selected from aluminum nitride (AlN), aluminum gallium nitride (AlGaN), or a combination thereof. The back barrier layer 230 provides carrier confinement in the channel region and suppresses leakage current.

The n-type doped III-nitride regions 240 are formed over the back barrier layer 230 and comprise a III-nitride semiconductor such as GaN, InGaN, or AlGaN with low aluminum percentage. The n-type doped III-nitride regions 240 are doped with silicon (Si) or other suitable n-type dopants at a doping density ranging from approximately 1×10\hat{ }16 cm\hat{ }−3 to over 1×10\hat{ }20 cm\hat{ }−3. The doping profile may be uniform or non-uniform. In one embodiment, the doping concentration is higher near the top surface of the n-type doped III-nitride regions 240 to facilitate low-resistance ohmic contact formation. The thickness of the n-type doped III-nitride regions 240 ranges from approximately 5 nm to over 200 nm.

The n-type doped III-nitride regions 240 are laterally spaced apart to define the channel region 245 therebetween. The source electrode 291 and drain electrode 292 are formed on the n-type doped III-nitride regions 240 on opposing lateral sides of the gate electrode 280. The n-type doped III-nitride regions 240 enable formation of low-resistance ohmic contacts to the source electrode 291 and drain electrode 292. The source and drain electrodes comprise Ti, Al, W, TiN, Au, Cu, or other suitable conductive materials.

The channel layer 250 is formed in the channel region 245 over the back barrier layer 230 and between the n-type doped III-nitride regions 240. The channel layer 250 comprises a III-nitride semiconductor (e.g., undoped or lightly doped GaN), although other III-nitride semiconductors including AlGaN are not precluded. The channel layer 250 may be thinner than, the same thickness as, or thicker than the n-type doped III-nitride regions 240. The channel layer 250 and subsequent gate structure layers are formed by epitaxial regrowth, for example by metal-organic chemical vapor deposition (MOCVD), molecular beam epitaxy (MBE), or hydride vapor phase epitaxy (HVPE), although other deposition methods are not precluded. The regrown layers may be substantially conformal, or may exhibit different growth rates in different directions, resulting in varying layer profiles depending on the regrowth conditions, crystal orientation, and deposition method.

The gate electrode 280 is formed over the gate structure, comprising one or more conductive materials including Ti, TiN, Al, Ni, W, Au, Cu, Co, Pt, silicides, and other suitable conductive materials. The gate electrode 280 footprint may be narrower than, the same width as, or substantially aligned with the uppermost gate structure layer.

The n-type doped III-nitride regions 240 are self-aligned to the channel layer 250. The device is free of conventional access regions between the gate electrode 280 and the source electrode 291 and drain electrode 292, thereby reducing the drawbacks associated with conventional GaN HEMTs as described in the Background.

### IV. First Embodiment

Referring to FIG. 2, a transistor device 200 according to a first embodiment of the invention includes: a substrate 210, a buffer layer 220, a back barrier layer 230, n-type doped III-nitride regions 240 formed over the back barrier layer 230 and defining a channel region 245 therebetween, a channel layer 250 formed in the channel region 245 and extending laterally beyond the channel region 245 onto a portion of the top surface of the n-type doped III-nitride regions 240, a barrier layer 260 formed over the channel layer 250, a p-type III-nitride (pGaN) layer 270 formed over the barrier layer 260, a gate electrode 280 formed over the p-type III-nitride layer 270, and source electrode 291 and drain electrode 292 formed on the n-type doped III-nitride regions 240 on opposing lateral sides of the gate electrode 280.

The barrier layer 260 comprises a III-nitride semiconductor having a wider bandgap than the channel layer 250, selected from AlN, AlGaN, InAlN, or combinations thereof. The barrier layer 260 may be formed as a single compositionally uniform layer, a layer with a graded aluminum composition, or a combination of sub-layers of differing III-nitride compositions, wherein the aluminum composition may vary continuously or in discrete steps through the thickness of the barrier layer 260. The total thickness of the barrier layer 260 ranges from approximately 1 nm to approximately 30 nm, and the aluminum content of the barrier layer 260 typically ranges from approximately 5% to approximately 100%, although other thicknesses and compositions are not precluded.

The p-type III-nitride layer 270 comprises a Mg-doped p-type III-nitride semiconductor (e.g., GaN), although other III-nitride semiconductors including AlGaN and InGaN are not precluded. The p-type III-nitride layer 270 may be formed by MOCVD, MBE, HVPE, or other suitable deposition methods. The p-type III-nitride layer 270 has a thickness ranging from approximately 10 nm to over 100 nm, and a Mg doping density ranging from approximately 1×10\hat{ }18 cm\hat{ }−3 to over 1×10\hat{ }20 cm\hat{ }−3 , although other thicknesses and doping densities are not precluded. The Mg doping profile may be uniform or non-uniform, with higher Mg concentration in a central region, at the surface, or near the interface between the p-type III-nitride layer 270 and the barrier layer 260, to optimize depletion characteristics and threshold voltage. The p-type III-nitride layer 270 depletes the channel in the channel region under zero gate bias, which may produce normally-off operation with a positive threshold voltage depending on the doping density of the p-type III-nitride layer 270, the thickness and composition of the barrier layer 260, and other design factors.

In the embodiment of FIG. 2, the channel layer 250 and the barrier layer 260 extend laterally beyond the channel region 245 onto at least a portion of the top surface of the n-type doped III-nitride regions 240. In this embodiment, the n-type doped III-nitride regions 240 are positioned underneath the channel layer 250 and the barrier layer 260 in the overlap region.

The channel layer 250 may extend onto a larger or smaller portion of the top surface of the n-type doped III-nitride regions 240 than shown in FIG. 2, including extending to or partially underneath the source electrode 291 and drain electrode 292. The barrier layer 260 may extend laterally the same as or less than the channel layer 250. The p-type III-nitride layer 270 may be substantially aligned with, or narrower than, the barrier layer 260.

### V. Second Embodiment

Referring to FIG. 3, a transistor device 200 according to a second embodiment of the invention has a structure similar to the first embodiment of FIG. 2, except that the channel layer 250 is laterally confined within the channel region 245 and does not extend onto the top surface of the n-type doped III-nitride regions 240. The barrier layer 260 extends laterally beyond the channel region 245 onto at least a portion of the top surface of the n-type doped III-nitride regions 240, and the p-type III-nitride layer 270 is formed over the barrier layer 260 with a gate electrode 280 formed over the p-type III-nitride layer 270.

In this embodiment, because the barrier layer 260 extends over the n-type doped III-nitride regions 240, the n-type doped III-nitride regions 240 are positioned underneath the barrier layer 260 in the overlap region. The barrier layer 260 may extend to or partially underneath the source electrode 291 and drain electrode 292. The p-type III-nitride layer 270 may be substantially aligned with, or narrower than, the barrier layer 260.

### VI. Third Embodiment

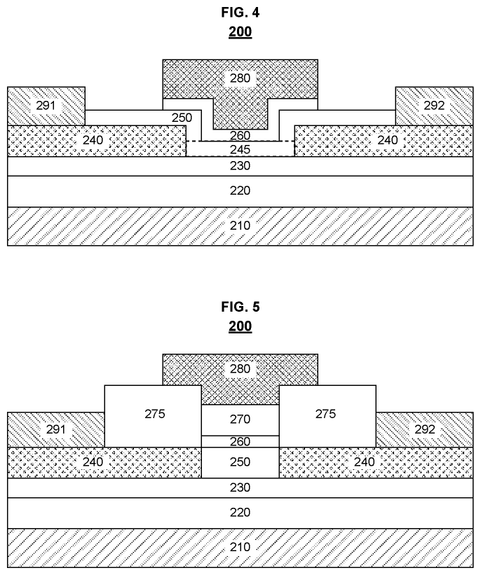

Referring to FIG. 4, a transistor device 200 according to a third embodiment of the invention includes the same substrate 210, buffer layer 220, back barrier layer 230, and n-type doped III-nitride regions 240 as described in Section III. The channel layer 250 and a barrier layer 260 are formed in the channel region 245 and extend laterally beyond the channel region 245 onto at least a portion of the top surface of the n-type doped III-nitride regions 240. In the embodiment illustrated in FIG. 4, the channel layer 250 extends laterally to the source electrode 291 and drain electrode 292. In this embodiment, no p-type III-nitride layer is present, and the gate electrode 280 is formed directly on the barrier layer 260. The barrier layer 260 is narrower than the channel layer 250. The channel layer 250 may extend onto a larger or smaller portion of the top surface of the n-type doped III-nitride regions 240 than shown in FIG. 4, including extending partially underneath the source electrode 291 and drain electrode 292. The barrier layer 260 may extend laterally the same as or less than the channel layer 250. The device may provide depletion-mode or enhancement-mode operation depending on the barrier layer thickness, composition, and other design factors.

### VII. Fourth Embodiment

Referring to FIG. 5, a transistor device 200 according to a fourth embodiment of the invention has a structure similar to the first embodiment of FIG. 2, including a barrier layer 260 formed over the channel layer 250, a p-type III-nitride layer 270 formed over the barrier layer 260, and a gate electrode 280 formed over the p-type III-nitride layer 270. In this embodiment, the channel layer 250, the barrier layer 260, and the p-type III-nitride layer 270 are all laterally confined within the channel region 245 and do not extend over the top surface of the n-type doped III-nitride regions 240. A dielectric layer 275 is formed on the n-type doped III-nitride regions 240 on opposing lateral sides of the gate structure, and the gate electrode 280 extends laterally over the dielectric layer 275. The dielectric layer 275 may comprise silicon nitride (SiN), silicon dioxide (SiO2), aluminum oxide (Al2O3), or other suitable dielectric materials, or a combination thereof, and may include one or more sub-layers of differing dielectric compositions.

### VIII. Additional Gate Structure Configurations

While the embodiments of FIG. 2, FIG. 3, and FIG. 5 illustrate a gate structure comprising a barrier layer 260 and a p-type III-nitride layer 270, and the embodiment of FIG. 4 illustrates a gate structure comprising a barrier layer 260 without a p-type III-nitride layer, additional gate structure configurations are contemplated and are not precluded.

In another embodiment, the gate structure comprises a barrier layer 260 formed over the channel layer 250, and a gate dielectric layer formed over the barrier layer 260. The gate dielectric layer may comprise silicon nitride (SiN), silicon dioxide (SiO2), aluminum oxide (Al2O3), hafnium oxide (HfO2), or other suitable dielectric materials, and may be deposited by atomic layer deposition (ALD), plasma-enhanced chemical vapor deposition (PECVD), or other suitable techniques. The gate electrode 280 is formed on the gate dielectric layer. This configuration may provide depletion-mode or enhancement-mode operation depending on the barrier layer thickness, composition, and gate dielectric properties.

In a further embodiment, the gate structure comprises a gate dielectric layer formed directly over the channel layer 250 without an intervening barrier layer, forming a metal-insulator-semiconductor (MIS) gate structure.

In yet another embodiment, the gate electrode 280 is formed directly on the channel layer 250. In a further embodiment, a p-type III-nitride layer may be formed directly on the channel layer 250 without an intervening barrier layer, and the gate electrode 280 is formed over the p-type III-nitride layer.

The lateral extent variations described in the foregoing embodiments, wherein layers may extend laterally beyond the channel region 245 or be laterally confined within the channel region 245, apply analogously to these additional gate structure configurations.

### IX. Fabrication Methods

The n-type doped III-nitride regions 240, channel layer 250, and gate structure layers may be formed by MOCVD, MBE, HVPE, ALD, PECVD, PVD, or other suitable deposition techniques as appropriate for the respective materials.

In a first fabrication method, the back barrier layer 230 and an n-type doped III-nitride layer are formed sequentially by epitaxial growth. The channel region 245 is then formed by removing a portion of the n-type doped III-nitride layer, for example by dry etching using inductively coupled plasma reactive ion etching (ICP-RIE), to form the n-type doped III-nitride regions 240 on opposing sides of the channel region 245. The back barrier layer 230 may serve as an etch stop layer during this etching step. The channel layer 250 and subsequent gate structure layers are then formed sequentially in the channel region 245 by epitaxial regrowth and/or deposition, for example by MOCVD or MBE for epitaxial III-nitride layers and by ALD or PECVD for gate dielectric layers.

In a second fabrication method, the back barrier layer 230 and the channel layer 250 are formed sequentially by epitaxial growth. The n-type doped III-nitride regions 240 are then formed by epitaxial growth in etched openings of the channel layer 250, such that the n-type doped III-nitride regions 240 are formed on the back barrier layer 230 on opposing sides of the remaining channel layer 250. The gate structure layers are then formed over the channel layer 250.

In the foregoing fabrication methods, epitaxial layers may be formed by blanket regrowth followed by etching to define the lateral extent of each layer, or by selective area regrowth using a dielectric masking layer to define the lateral extent without subsequent etching.

### X. Device Operation and Advantages

The embedded channel structure achieves higher device performance, including higher saturation current (Idmax) and improved transconductance linearity, compared to conventional GaN HEMTs with 2DEG-based access regions.

The embedded channel structure replaces the conventional 2DEG-based access regions with n-type doped III-nitride regions 240 that are self-aligned to the channel layer 250. The n-type doped III-nitride regions 240 effectively shield against surface defect-induced electron trapping that causes current collapse and dynamic on-resistance degradation in conventional devices. The n-type doped III-nitride regions 240 also enable formation of low-resistance ohmic contacts to the source and drain electrodes.

The transistor device may additionally incorporate features known in the art, including but not limited to passivation layers, field plates, surface treatment layers, and inter-metal dielectrics, which are compatible with and do not limit the scope of the present invention.

The transistor device may be configured for enhancement-mode (normally-off) operation with a positive threshold voltage, or for depletion-mode (normally-on) operation with a negative threshold voltage, depending on the gate structure configuration, layer compositions, and layer thicknesses.

What is claimed is:

1. A transistor device comprising:
a substrate;
a buffer layer over the substrate;
a back barrier layer over the buffer layer, the back barrier layer comprising a III-nitride semiconductor;
n-type doped III-nitride regions formed over the back barrier layer, the n-type doped III-nitride regions being laterally spaced apart to define a channel region therebetween;
a channel layer comprising a III-nitride semiconductor formed in the channel region over the back barrier layer;
a gate structure formed over the channel layer;
a gate electrode formed over the gate structure; and
source and drain electrodes formed on the n-type doped III-nitride regions on opposing lateral sides of the gate electrode;
wherein at least one of the gate structure and the gate electrode extends laterally to overlap with or be substantially aligned with an inner lateral edge of at least one of the n-type doped III-nitride regions.

2. The transistor device of claim 1, wherein the gate structure comprises a barrier layer formed over the channel layer, the barrier layer comprising a III-nitride semiconductor having a wider bandgap than the channel layer.

3. The transistor device of claim 2, wherein the gate structure further comprises a p-type III-nitride layer formed over the barrier layer, and the gate electrode is formed over the p-type III-nitride layer.

4. The transistor device of claim 3, wherein the p-type III-nitride layer comprises Mg-doped p-type gallium nitride having a thickness ranging from approximately 10 nm to over 100 nm and a Mg doping density ranging from approximately 1×10\hat{ }18 cm\hat{ }−3 to over 1×10\hat{ }20 cm\hat{ }−3 .

5. The transistor device of claim 2, wherein the gate electrode is formed on the barrier layer or on a gate dielectric layer formed over the barrier layer.

6. The transistor device of claim 1, wherein the gate structure comprises a gate dielectric layer formed over the channel layer, and the gate electrode is formed on the gate dielectric layer.

7. The transistor device of claim 1, wherein the n-type doped III-nitride regions comprise a III-nitride semiconductor selected from the group consisting of GaN, InGaN, and AlGaN, doped with silicon at a doping density ranging from approximately 1×10\hat{ }16 cm\hat{ }−3 to over 1×10\hat{ }20 cm\hat{ }−3, and having a thickness ranging from approximately 5 nm to over 200 nm.

8. The transistor device of claim 1, wherein the channel layer extends laterally beyond the channel region onto a portion of a top surface of the n-type doped III-nitride regions.

9. The transistor device of claim 1, wherein the channel layer is laterally confined within the channel region and does not extend over a top surface of the n-type doped III-nitride regions.

10. The transistor device of claim 2, wherein the barrier layer extends laterally beyond the channel region onto at least a portion of a top surface of the n-type doped III-nitride regions.

11. The transistor device of claim 3, wherein lateral edges of the p-type III-nitride layer and lateral edges of the barrier layer are substantially aligned with each other.

12. The transistor device of claim 3, wherein the p-type III-nitride layer is narrower than the barrier layer.

13. The transistor device of claim 2, wherein lateral edges of the barrier layer are substantially aligned with lateral edges of the channel layer.

14. The transistor device of claim 1, wherein the transistor device is configured to operate in an enhancement mode having a positive threshold voltage.

15. A method of fabricating a transistor device, comprising:
forming a buffer layer over a substrate;
forming a back barrier layer over the buffer layer, the back barrier layer comprising a III-nitride semiconductor selected from the group consisting of aluminum nitride (AlN), aluminum gallium nitride (AlGaN), and combinations thereof;
forming n-type doped III-nitride regions over the back barrier layer;
forming a channel region between the n-type doped III-nitride regions to expose the back barrier layer;
forming a channel layer comprising a III-nitride semiconductor in the channel region over the back barrier layer;
forming a gate structure over the channel layer;
forming a gate electrode over the gate structure; and
forming source and drain electrodes on the n-type doped III-nitride regions on opposing lateral sides of the gate electrode.

16. The method of claim 15, wherein forming the gate structure comprises forming a barrier layer over the channel layer, the barrier layer comprising a III-nitride semiconductor having a wider bandgap than the channel layer.

17. The method of claim 16, wherein forming the gate structure further comprises forming a p-type III-nitride layer over the barrier layer.

18. The method of claim 15, wherein forming the channel region comprises removing a portion of the n-type doped III-nitride regions by dry etching to expose the back barrier layer.

19. The method of claim 15, wherein the channel layer and the gate structure extend laterally beyond the channel region onto at least a portion of a top surface of the n-type doped III-nitride regions.

20. A method of fabricating a transistor device, comprising:
forming a buffer layer over a substrate;
forming a back barrier layer over the buffer layer;
forming a channel layer comprising a III-nitride semiconductor over the back barrier layer;
forming n-type doped III-nitride regions over the back barrier layer on opposing sides of the channel layer by removing portions of the channel layer and forming the n-type doped III-nitride regions in the removed portions;
forming a gate structure over the channel layer;
forming a gate electrode over the gate structure; and
forming source and drain electrodes on the n-type doped III-nitride regions on opposing lateral sides of the gate electrode.
